(19) United States
(12) Patent Application Publication
(10) Pub. No.: US 2022/0050413 A1
(43) Pub. Date: Feb. 17, 2022

(54) CONTROL OF PRINTER HEATING ELEMENTS BASED ON INPUT VOLTAGES

(71) Applicant: Hewlett-Packard Development Company, L.P., Spring, TX (US)

(72) Inventors: Duane A. Koehler, Vancouver, WA (US); Robert Yraceburu, Vancouver, WA (US)

(73) Assignee: Hewlett-Packard Development Company, L.P., Spring, TX (US)

(21) Appl. No.: 17/288,538

(22) PCT Filed: Apr. 30, 2019
(86) PCT No.: PCT/US2019/030025

§ 371 Date: Apr. 25, 2021

(51) Int. Cl. G03G 15/00; G05D 23/19; H05B 1/02; G01R 19/00; G01K 7/22; G01K 7/02

(52) U.S. Cl. CPC G03G 15/80; G05D 23/1919; H05B 1/02; H03K 5/1565; G01K 7/22; G01K 7/02; G01R 19/0084

(57) ABSTRACT

An apparatus may include a power connection to receive an input power and a volt meter coupled to the power connection. The volt meter may be to measure an input voltage of the input power. A controller may be coupled to a heating element and the volt meter. The controller may control the heating element based on the input voltage measured by the volt meter.

### BACKGROUND

A heating element may be used as part of a printer. Heat may be applied to transfer dye from one medium to another, to evaporate moisture from ink or paper, to melt a printing medium or to heat, fuse, or sinter powder, such as the case with three-dimensional (3D) printers, or to fuse toner in an electrophotographic printer. Multiple heating elements may be used, along with peripheral components to provide power to and control the heating of the elements at the proper time.

### BRIEF DESCRIPTION OF THE DRAWINGS

Various examples will be described below referring to the following figures:

FIG. 1 shows an apparatus comprising a volt meter, a controller, and a heating element in accordance with various examples;

FIG. 2 shows an apparatus comprising a volt meter, a pulse width modulator, and a heating element in accordance with various examples;

FIG. 3 shows an apparatus comprising a volt meter, a pulse width modulator, and a switch to control a flow of power to a heating element in accordance with various examples; and

FIG. 4 shows a method of determining a voltage value of a power supply, setting a maximum pulse width based on the voltage value, and controlling a heating element using a pulse wave in accordance with various examples.

### DETAILED DESCRIPTION

Different countries have different standards for the electricity provided from a wall outlet. Some of the standards allow for a wider range of voltages to be supplied than the other standards. Designing equipment to make use of the varying possible voltage values may involve design compromises, such as in the power supplied to heating elements and the amount of time allowed to pre-warm components before use. Even within a single country, different locations may have sufficiently different power supplies to introduce inefficiencies in products designed to operate on such power systems.

By measuring a voltage value of the input power provided from a wall outlet, a device may modify its operation according to local power conditions, or even as power conditions change over time. For heating elements, power may be delivered to the heating element differently based on the local power conditions.

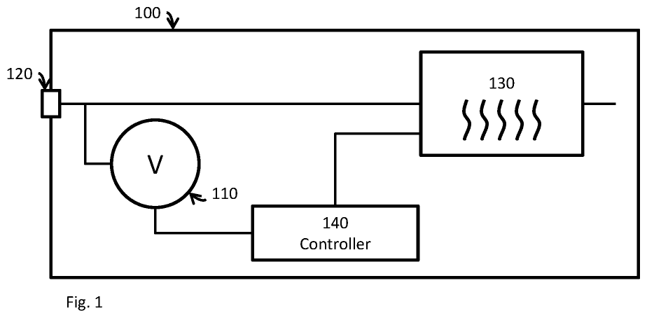

FIG. 1 shows an apparatus 100 comprising a volt meter 110, a controller 140, and a heating element 130 in accordance with various examples. The apparatus also comprises a power connection 120. The power connection 120 may receive input power, such as from a wall outlet. The volt meter 110 may measure a voltage of the input power, such as a root-mean-squared (RMS) voltage value of an alternating current (AC) power supply. The controller 140 may receive the voltage measurement from the volt meter 110. The controller 140 may control the heating element 130 based on the voltage measurement. The heating element 130 may be used for heat-based printing, such as in dye sublimation printers, 3D printers, inkjet printers, electrophotographic printers, Z-ink printers, or laser printers.

In various examples, the controller 140 may control the heating element 130 via a drive signal. The drive signal may include a series of pulses with a pulse width. The pulse width may control how much power is provided to the heating element 130. When the drive signal is high, electricity may be provided to the heating element 130. The duty cycle or frequency of the drive signal may also be modified to control the delivery of power to the heating element. A constant-high drive signal may provide full power to the heating element 130. A 50% duty cycle may provide half power to the heating element 130. Modifying the pulse width or frequency may modify the duty cycle of the drive signal.

In various examples, the controller 140 may control the heating element 130 by limiting the current draw of the heating element 130. This may be done by limiting the instantaneous current draw, or limiting the average current draw over a period of time.

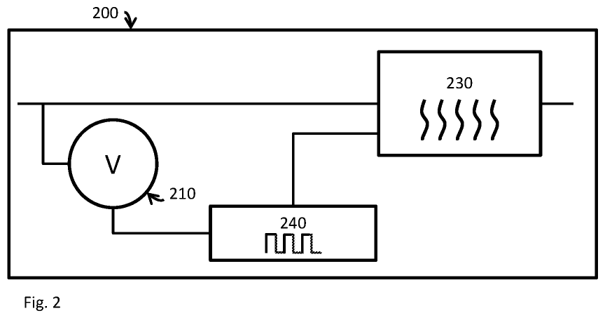

FIG. 2 shows an apparatus 200 comprising a volt meter 210, a pulse width modulator 240, and a heating element 230 in accordance with various examples. The volt meter 210 may measure an input voltage of an input power to the apparatus 200. The pulse width modulator 240 may provide a drive signal to the heating element 230. The drive signal may be based on the voltage value measured by the volt meter 210. The drive signal may include a frequency and pulse width controlled by the pulse width modulator 240.

In various examples, the drive signal from the pulse width modulator 240 may be limited by a pulse width cap. The pulse width cap may specify a maximum pulse width of the drive signal. If a set frequency is used, the pulse width, subject to the pulse width cap, may correspond to a duty cycle of the drive signal. The pulse width cap may be adjusted based on the voltage value measured by the volt meter 210. By way of example, the pulse width cap may be a 7-bit number allowing a value between 0 and 127. If the voltage value is 110 volts RMS (VRMS) or less, the pulse width cap may be set at 127. A pulse width cap of 127 may provide maximum available power to the heating element 230. For voltage values above 110 VRMS, a lower pulse width cap may be used, such as 107 at 120 VRMS or 69 at 150 VRMS. The lower pulse width caps may cause less average power to be provided to the heating element 230 by reducing the amount of time the heating element 230 receives power. Though higher voltages may be applied, limiting the time the higher voltage is applied may limit the average power provided to the heating element 230 over time. Adjustment of the pulse width cap may include directly setting the pulse width cap, or it may include providing a scaling factor for the pulse width cap.

In various examples, adjusting the pulse width cap may cause the current draw of the heating element 230 to be limited. The current draw may be limited to be beneath the value of a fuse, circuit, or circuit breaker, internal or external to the apparatus 200. The limitation on the current draw may be based on limiting the average square of the current draw over a set amount of time, which may limit the average power delivery to the heating element 230. The type and amount of current limitation may be based on the fuses, circuits, or circuit breakers used in conjunction with the apparatus 200.

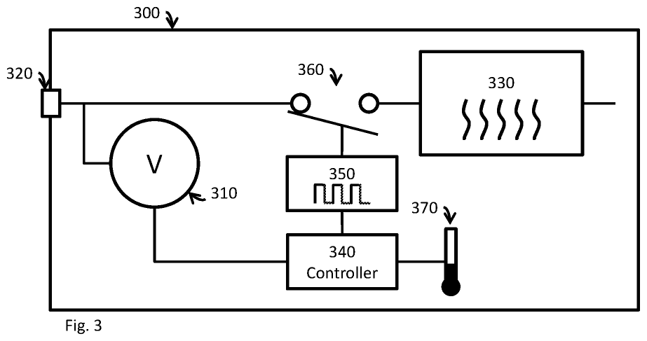

FIG. 3 shows an apparatus 300 comprising a volt meter 310, a pulse width modulator 350, and a switch 360 to control a flow of power to a heating element 330 in accordance with various examples. The apparatus 300 may also include a power connection 320 to receive an input power to the apparatus 300, a controller 340, and a temperature sensor 370.

The volt meter 310 is coupled to the power connection 320. The volt meter 310 may measure a voltage of the power connection 320, such as a VRMS value provided by an AC wall outlet.

The controller 340 is coupled to the volt meter 310. The controller 340 may receive the voltage value measured by the volt meter 310. The controller 340 may also be coupled to a temperature sensor 370, such as a thermistor or thermocouple, and to the pulse width modulator 350. The controller 340 may control the pulse width modulator 350 to provide a drive signal. The drive signal may have a frequency and a pulse width. Modifying the pulse width may modify the duty cycle of the drive signal. The controller 340 may determine a pulse width cap to use with the pulse width modulator to cap the width of the pulse, and thus the duty cycle. The controller 340 may determine the pulse width cap based on the voltage value from the volt meter 310. The controller 340 may also determine a pulse width to use during operation of the apparatus 300. The operation may be during a warmup operation or during normal use of the apparatus 300. The pulse width may be based on a temperature value provided from the temperature sensor 370. The drive signal generated by the pulse width modulator 350 may thus be controlled based on the voltage value from the volt meter 310 and the temperature from the temperature sensor 370. In various examples, the pulse width modulator 350 may be part of the controller 340.

The pulse width modulator 350 may provide the drive signal to a switch 360. The switch 360 may be an electro-mechanical relay, triode for alternating current (TRIAC), or other circuit switching device that selectively provides power from the power connection 320 to the heating element 330. The amount of power consumed by the heating element 330 is based on the voltage value of the input power. The heating element 330 may be a resistive heating element. When the switch 360 is closed, the power consumed may be based on the expression v²/R, based on Ohm's Law, where V is the voltage value provided to the heating element 330 and R is the resistive value of the heating element 330. The power consumed may increase as the voltage of the power supply rises. Thus capping the average power provided to the heating element 330 based on the voltage of the power supply may be useful. The drive signal may cause the switch 360 to open and close over time. The larger the pulse width, the longer the switch 360 may be closed, thus providing power to the heating element 330. When the switch 360 is open, current may not be supplied to the heating element 330. By controlling the switch 360 via the drive signal, the average current provided to the heating element 330 over time may be controlled.

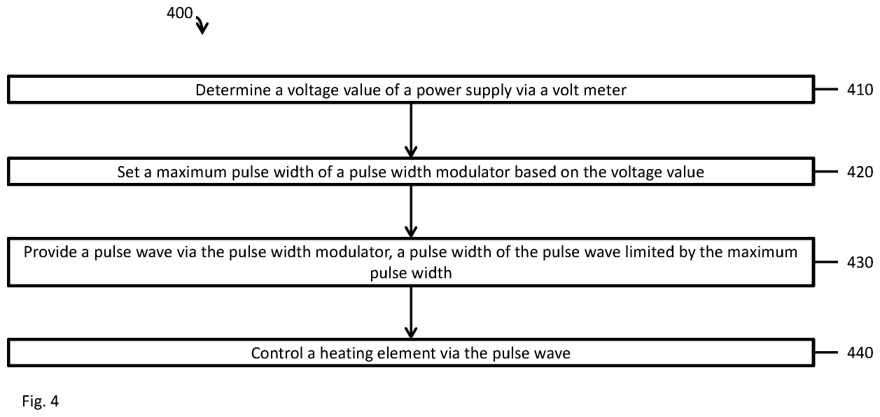

FIG. 4 shows a method 400 of determining a voltage value of a power supply, setting a maximum pulse width based on the voltage value, and controlling a heating element using a pulse wave in accordance with various examples. The method 400 includes determining a voltage value of a power supply via a volt meter (410). The method 400 includes setting a maximum pulse width of a pulse width modulator based on the voltage value (420). The method 400 includes providing a pulse wave via the pulse width modulator, a pulse width of the pulse wave limited by the maximum pulse width (430). The method 400 includes controlling a heating element via the pulse wave (440).

The pulse wave may be a signal alternating between high and low voltage values or between a digital value of ones and zeroes, such as may be created by a pulse width modulator. The pulse wave may include a frequency and a pulse width or duty cycle.

In various examples, the pulse wave may be used to control the state of a switch, alternating the switch between an open or closed state. When the pulse wave is high, the switch may be closed. When the pulse wave is low, the switch may be open. These states may also be reversed, so the switch is open when the pulse wave is high and closed when the pulse wave is low. The switch may control the supply of power from a power supply to the heating element.

In various examples, the voltage value supplied by a wall outlet may vary over time. During the middle of the night, the voltage value may be 120 VRMS. During the middle of the day, when a heavy load is being exerted on the power grid, the voltage value may drop to 105 VRMS or lower. This change in voltage value may affect the efficiency or performance of a device. The device may thus measure the voltage value of the power supply at various points in time. This may be performed at startup, performed once every hour, performed once every minute, performed multiple times per second, or at other points in time, depending on the specifications of the device. If the voltage value changes from one point in time to another, the pulse width cap may be modified based on the voltage value change.

The above discussion is meant to be illustrative of the principles and various examples of the present disclosure. Numerous variations and modifications will become apparent to those skilled in the art once the above disclosure is fully appreciated. It is intended that the following claims be interpreted to embrace all such variations and modifications.

What is claimed is:

1. An apparatus comprising:
a power connection to receive an input power;
a volt meter coupled to the power connection, the volt meter to measure an input voltage of the input power;
a heating element to heat a printer; and
a controller coupled to the volt meter and the heating element, wherein the controller is to control the heating element based on the input voltage.

2. The apparatus of claim 1 comprising:
a switch to couple the heating element to the power connection; and
a pulse width modulator to provide a drive signal to the switch, the drive signal to control a state of the switch, wherein the control of the heating element by the controller includes control of the pulse width modulator.

3. The apparatus of claim 2, wherein the controller is to determine whether the input voltage is greater than a predetermined voltage value, the control of the pulse width modulator includes application of a pulse width scaling factor to adjust a maximum pulse width of the drive signal when the input voltage is greater than the predetermined voltage value, and wherein the pulse width scaling factor is based on the input voltage.

4. The apparatus of claim 1, wherein, to control the heating element, the controller is to limit a current draw of the heating element.

5. The apparatus of claim 1 comprising a temperature sensor to measure a temperature, wherein the control of the heating element is based on the temperature.

6. An apparatus comprising:
a volt meter to measure an input voltage of an input power;
a heating element to generate heat; and
a pulse width modulator coupled to the heating element, the pulse width modulator to provide a drive signal, the pulse width modulator to control the generation of heat by the heating element via the drive signal, and the drive signal based on the input voltage.

7. The apparatus of claim 6, wherein the provision of the drive signal includes an adjustment of a pulse width cap of the pulse width modulator, and wherein the pulse width cap is to control a maximum duty cycle of the drive signal.

8. The apparatus of claim 7, wherein, to control the maximum duty cycle of the drive signal, the pulse width cap is to set a maximum limit of a current draw of the heating element.

9. The apparatus of claim 8, wherein the maximum limit of the current draw includes a maximum limit of an average of a square of the current draw.

10. The apparatus of claim 6 comprising a switch, the switch coupled to the heating element, the switch to receive the input power, and the switch to provide the input power to the heating element based on the drive signal.

11. A method comprising:
determining a voltage value of a power supply via a volt meter;
setting a maximum pulse width of a pulse width modulator based on the voltage value;
providing a pulse wave via the pulse width modulator, a pulse width of the pulse wave limited by the maximum pulse width; and
controlling a heating element via the pulse wave.

12. The method of claim 11 comprising:
controlling a state of a switch via the pulse wave; and
providing a power of the power supply to the heating element via the switch.

13. The method of claim 11 comprising limiting a current draw of the heating element based on the voltage value.

14. The method of claim 11 comprising:
measuring a temperature via a temperature sensor; and
modifying the pulse width of the pulse wave based on the temperature.

15. The method of claim 11 comprising:
determining a second voltage value of the power supply via the volt meter, the second voltage value being different than the first voltage value; and
modifying the maximum pulse width based on the second voltage value.
